(19) United States
(12) Patent Application Publication
(10) Pub. No.: US 2007/0295951 A1
(43) Pub. Date: Dec. 27, 2007

(54) Light-emitting diode incorporating an array of light extracting spots

(76) Inventors: Jen-Inn Chyi, Pingzhen City (TW); Chia-Ming Lee, Toucheng Town (CN); Jui-Cheng Chang, Sikou Township (TW); Tsung-Liang Chen, Nantou City (TW); Shih-Ling Chen, Nantou City (TW)

Correspondence Address: DAVID I. ROCHE;BAKER & MCKENZIE LLP, 130 EAST RANDOLPH DRIVE, CHICAGO, IL, 60601, US

(21) Appl. No.: 11/474,878

(22) Filed: Jun. 26, 2006

(51) Int. Cl. H01L 31/00

(52) U.S. Cl. 257/14

(57) ABSTRACT

A light-emitting diode includes an optical layer formed in an array of substantially equidistant light extracting spots integrated to its multi-layer structure. The array of light extracting spots includes a distribution of juxtaposed hexagon patterns. The layer thickness of the light extracting spots is less than 800 Å, and preferably around 500 Å.

### FIELD OF THE INVENTION

The present invention generally relates to the manufacture of semiconductor light-emitting diodes, and more specifically to a light-emitting diode having improved light extraction efficiency.

2. Description of the Related Art

A light-emitting diode is conventionally composed of a multi-layer structure including a light-emitting layer sandwiched between n-type and p-type semiconductor layers. The light-emitting layer may be a single or multi-layered structure made of active nitride semiconductor compounds. An electric voltage bias applied between the electrodes of the light-emitting diode creates an injection of electrons and/or holes which flow through the n-type and p-type semiconductor layers and pass through the light-emitting layer where they recombine to produce light. The light generated from the light-emitting layer propagates in all directions, and exits the light-emitting diode through every exposed surface. To effectively achieve its illumination purpose, it is usually needed to direct the light exiting the light-emitting diode into a desired direction of emission.

Conventionally, the light efficiency of the light-emitting diode can be characterized through a number of indicative factors. One factor is the light extraction efficiency, which is the ratio of the amount of light leaving the light-emitting diode relative to the amount of light produced in the light-emitting diode. Practically, the amount of light leaving the light-emitting diode is less than the amount of light produced in the light-emitting diode due to diverse inner absorption through the different layers constituting the light-emitting diode. To increase the light extraction efficiency, one conventional approach is to place reflector layers inside the multi-layer structure of the light-emitting diode to redirect light along useful directions.

To address the foregoing issue, one approach known in the art consists of forming a p-type electrode made of silver (Ag) on the p-type layer of the light-emitting diode. This technique is described in, for example, U.S. Pat. No. 6,194,743, the disclosure of which is incorporated herein by reference. The high reflectance of Ag contributes to form a reflective p-type electrode capable of redirecting light towards the substrate, and absorption through the p-type electrode can be thereby prevented.

Another approach known in the art incorporates an optical layer in the multi-layered structure to promote the propagation of light along useful light paths. This technique is described in, for example, U.S. Pat. No. 6,657,236 to Thibeault et al., the disclosure of which is also incorporated herein by reference. The optical layer is formed in an array of light extraction elements configured to scatter and disperse light emitted from the light-emitting layer.

U.S. Pat. No. 6,870,191 discloses another technique in which a light-emitting diode has a sapphire substrate surface etched to form recesses and protruding portions, the disclosure of which is also incorporated herein by reference. Light generated from the light-emitting region can be scattered or diffracted by the recesses and protruding portions to improve the light extraction. The etching of the substrate conventionally requires the use of a metallic mask, which may adversely produce metallic residues contaminating subsequent growth processes. This method thus is not economic and produces undesirable contaminants.

The aforementioned prior art discloses various technical approaches which may need further improvement to increase the light intensity of a light-emitting diode.

### SUMMARY OF THE INVENTION

The application describes a light-emitting diode having improved light extraction efficiency and a manufacture process of forming the light-emitting diode.

In an embodiment, the light-emitting diode comprises a multi-layer structure comprised of a plurality of nitride semiconductor layers stacked over a substrate and including a light-emitting layer, a plurality of electrodes for applying a driving current to illuminate the light-emitting diode, and an optical layer integrated to the multi-layer structure, wherein the optical layer forms an array of substantially equidistant light extracting spots.

According to an embodiment, the array of the light extracting spots includes a juxtaposition of hexagon patterns. In some instances, the optical layer is made of a material compound including SiOₓ, SiNₓ, Si₃N₄, SiC, SiOₓN_{y}, ZnSe, TiO₂, or Ta₂O₅. In some embodiments, the thickness of the optical layer is less than 800 angstroms, and preferably about 500 angstroms. In variant embodiments, one light extracting spot has a surface area in a hexagonal shape. In some variations, the light-emitting diode has a luminous intensity above about 150 mcd.

The application also describes a process of forming a light-emitting diode. According to an embodiment, the process comprises forming a multi-layer structure including at least one light-emitting layer, forming electrodes for supplying a driving current through the multi-layer structure, and forming an optical layer integrated to the multi-layer structure and comprised of an array of substantially equidistant light extracting spots.

In some embodiments, the manufacture process includes forming the optical layer at an interface between two layers of the multi-layer structure. In some example of implementations, the optical layer is formed over a surface of a substrate, followed with patterning the optical layer to form an array of substantially equidistant light extracting spots, and stacking a plurality of layers including the light-emitting layer over the optical layer.

In some variations, the manufacture process further includes forming a buffer layer covering the optical layer, and forming a plurality of nitride semiconductor layers on the buffer layer.

In some instances, the patterning the optical layer to form an array of substantially equidistant light extracting spots includes performing a photolithography to form a photoresist pattern, and etching through the photoresist pattern.

The foregoing is a summary and shall not be construed to limit the scope of the claims. The operations and structures disclosed herein may be implemented in a number of ways, and such changes and modifications may be made without departing from this invention and its broader aspects. Other aspects, inventive features, and advantages of the invention, as defined solely by the claims, are described in the non-limiting detailed description set forth below.

### BRIEF DESCRIPTION OF THE DRAWINGS

FIGS. 1A through 1H are schematic views of a process of forming a light-emitting diode according to an embodiment of the invention;

FIG. 2 is a schematic view illustrating array patterns of light extracting spots arranged according to an embodiment of the invention;

FIG. 3 is a data chart showing the variation of characteristic parameters of a light-emitting diode according to the thickness of an array pattern of light extracting spots distributed according to the invention; and

FIG. 4 is a schematic view of a test system implementation for evaluating a light intensity of a light-emitting diode according to an embodiment of the invention.

### DETAILED DESCRIPTION OF THE EMBODIMENTS

The application describes a light-emitting diode and its manufacturing process which can improve light extraction efficiency, and increase the light intensity of a light-emitting diode. The light-emitting diode is formed with a multi-layer structure including layers of nitride semiconductor compounds. The multi-layer structure incorporates an optical layer configured with an array pattern of light extracting spots which can effectively refract and scatter light to improve light extraction. “Nitride semiconductor compounds” herein refer to GaN, AlGaN, InGaN, AlInGaN or like compounds at least comprised of any combinations of Al, In, Ga and N elements.

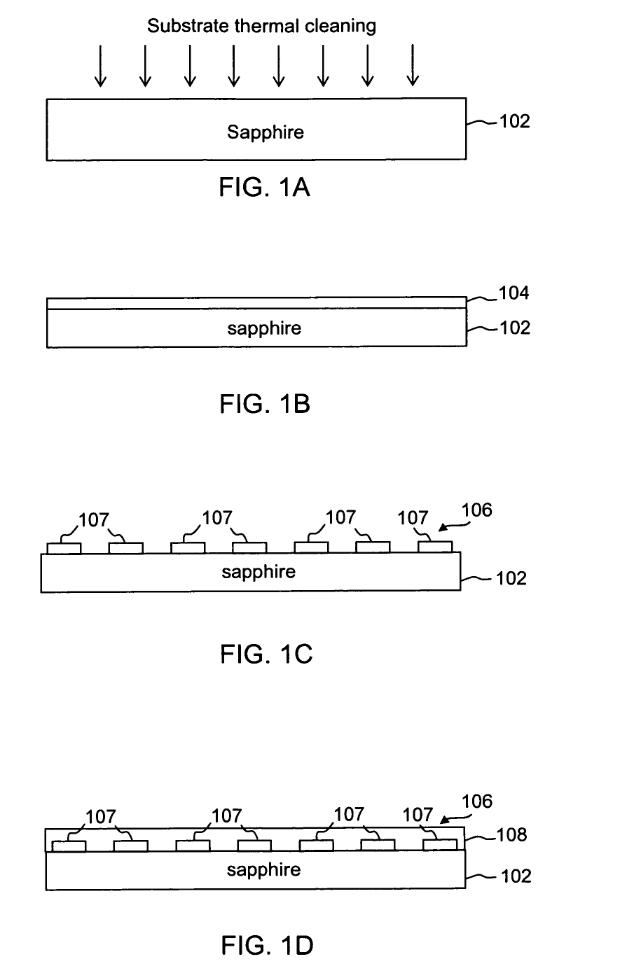

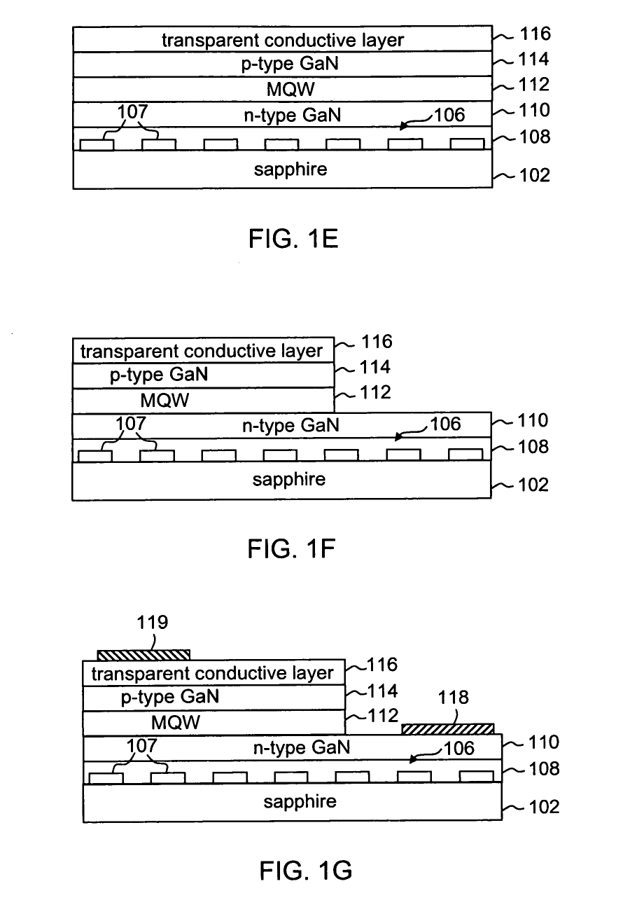

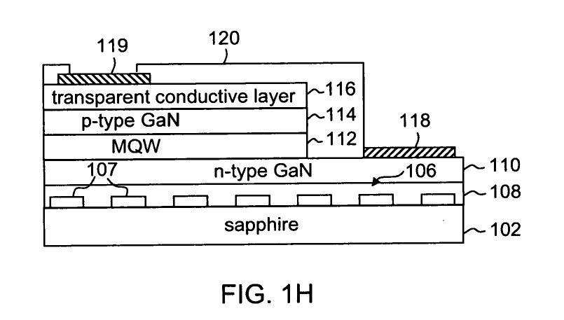

FIGS. 1A through 1H are schematic views of a process of manufacturing a light-emitting diode according to an embodiment of the invention. In FIG. 1A, a sapphire substrate 102 initially undergoes a thermal cleaning process. According to an embodiment, the thermal cleaning process includes heating the substrate 102 to a temperature above 1000° C. while introducing H₂ and/or N₂ at about 5 slm (standard liter per min) in a pressure environment kept at about 1000 mbar. A person skilled in the art will readily appreciate that the substrate may be made of other suitable transparent materials such as silicon, silicon carbide (SiC) or the like.

Referring to FIG. 1B, an optical layer 104 is formed on the substrate 102. In an embodiment of the invention, the optical layer 104 is made of silicon dioxide (SiO₂). More generally, other compound materials may be suitable, including SiOₓ, SiₓN_{y} such as Si₃N₄, SiC, SiOₓN_{y}, ZnSe, TiO₂, or Ta₂O₅, where x and y indicate suitable element ratio numbers in each compound. Referring to the illustrated embodiment, silicon dioxide is deposited on the surface of the substrate 102 by chemical vapor deposition. Sputtering or evaporation techniques may also be possible to form silicon dioxide.

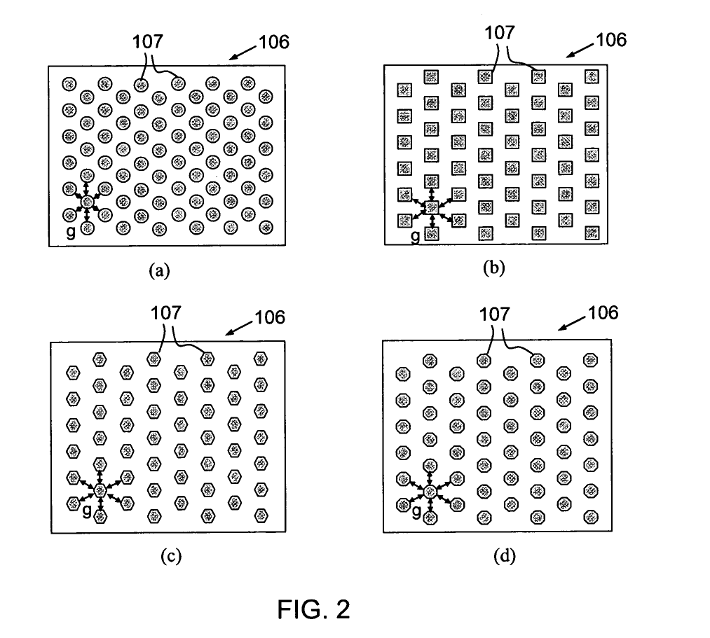

Referring to FIG. 1C, the optical layer 104 is etched through an appropriate pattern layer to form an array of light extracting pattern 106 distributed over the surface of the substrate 102. The pattern layer can be a photoresist layer deposited, exposed and developed according to a photolithography technique to form a suitable photoresist pattern. The light extracting pattern 106 preferably includes light extracting spots 107 distributed in array over a surface of the substrate 102. A preferable distribution pattern of the light extracting spots 107 will be described further below with reference to FIG. 2.

Referring to FIG. 1D, a buffer layer 108 is formed on the light extracting pattern 106. In an embodiment, the buffer layer 108 is made of undoped GaN deposited with a thickness sufficient to cover the light extracting pattern 106 on the surface of the substrate 102. Other materials such as AlGaN, InGaN, AlInGaN or like nitride semiconductor compounds may also be suitable for the buffer layer 108, which is used to reduce a crystalline lattice mismatch of the substrate 102 and the light extracting pattern 106 with nitride semiconductor layers subsequently formed thereon. The buffer layer 108 may be deposited by metalorganic chemical vapor deposition (MOCVD), vapor phase epitaxy (VPE), or molecular beam epitaxy (MBE) techniques.

Next referring to FIG. 1E, a multilayered structure is stacked on the buffer layer 108. In the illustrated embodiment, the multilayered structure includes an n-type contact layer 110, a light-emitting layer 112, a p-type contact layer 114, and a transparent conductive layer 116. The n-type contact layer 110, light-emitting layer 112, and p-type contact layer 114 may be formed using metalorganic chemical vapor deposition (MOCVD), vapor phase epitaxy (VPE), or molecular beam epitaxy (MBE) techniques. The transparent conductive layer 116 may be a transparent conducting oxide such as indium tin oxide deposited by sputtering, for example.

In the illustrated embodiment, the n-type contact layer 110 can exemplary be GaN doped with Si n-type doping elements, formed by a metalorganic chemical vapor deposition technique using trimethyl gallium (TMG), ammonium (NH₃) and monosilane (SiH₄), for example. The light-emitting layer 112 may include a multiple quantum well structure formed of well layers alternately stacked with barrier layers (not shown) made of nitride semiconductor compounds including nitrogen (N), indium (In) and gallium (Ga) deposited by a metalorganic chemical vapor deposition technique. The p-type contact layer 114 may be made of GaN including magnesium (Mg) doping impurities formed by a metalorganic chemical vapor deposition technique. The deposition conditions may be adjusted so that the p-type contact layer 114 can be deposited with active doping impurities without the need of a subsequent annealing process.

Referring to FIG. 1F, an area encompassing portions of the transparent conductive layer 116, the p-type contact layer 114 and the light-emitting layer 112 is etched until a portion of the n-type contact layer 110 is exposed.

Referring to FIG. 1G, an n-type electrode 118 is formed on the exposed area of the n-type contact layer 110, and a p-type electrode 119 is formed on the p-type contact layer 116.

Referring to FIG. 1H, a sealing passivation layer 120 is formed to cover the exposed areas of the transparent conductive layer 116 and n-type GaN layer 110, while exposing the electrodes 118 and 119. The passivation layer 120 can be made of SiO₂, for example. The exposed electrodes 118 and 119 can be connected through conductive wires or flip chip mount to a power source to drive illumination of the light-emitting diode. The power electric current creates a movement of electrons and holes through the n-type contact layer 110 and the p-type contact layer 114 which recombine within the light-emitting layer 112 to produce light.

FIG. 2 is a planar view illustrating embodiments of array patterns implemented for the light extracting pattern according to the invention. The light extracting pattern 106 includes a plurality of light extracting spots 107 uniformly distributed in array over a surface area of the substrate 102. The spots 107 are preferably placed in an equidistant distribution where each spot is equidistant from its neighboring spots. In other words, every pair of adjacent spots 107 in the array pattern has a same inter-spot distance “g”.

In the illustrated embodiments, the light extracting spots 107 are exemplary distributed in juxtaposed hexagon patterns, where spots 107 are respectively placed at the corners and the centre of each hexagon. The distance “g” between two adjacent spots is between about 0.5 μm and 10 μm. As shown in FIG. 2, the projection of one spot 107 in a plane parallel to the substrate may have a circular shape (a), a rectangular shape (b), a hexagonal shape (c), or an octagonal shape (d). The size of each spot 107 can be approximated by a circle circumscribing each spot and having a diameter of about 3 μms. The pattern distribution of the light extracting spots 107 thereby configured can effectively refract and scatter light to improve light extraction efficiency. A preliminary test shows that an improved light extraction is obtained for an array pattern of spots 107 having a hexagonal shape (c) with an inter-spot distance of about 2 μm.

A study conducted by the inventors of this application show that another factor of the light extracting pattern determines the light extraction efficiency of the light-emitting diode.

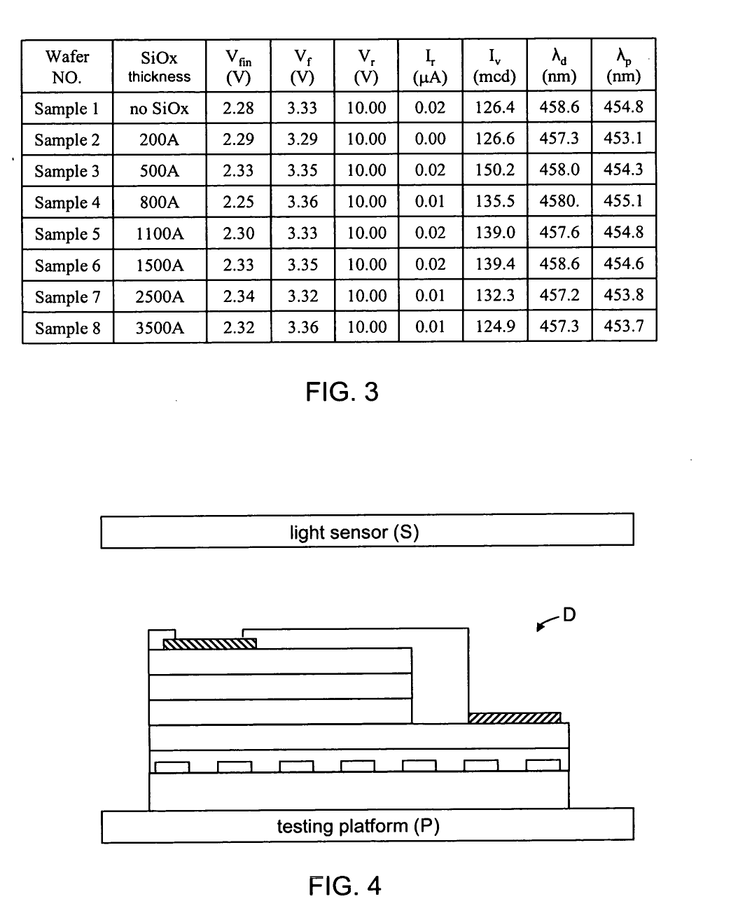

Reference now is made to FIGS. 3 and 4 to describe an experiment conducted according to an embodiment of the invention to evaluate the light extraction efficiency according to the thickness of the light extracting pattern. Samples of light-emitting diodes are formed with a same manufacture process, which can exemplary be implemented according to the description of FIGS. 1A through 1H. Each sample differs by the thickness of the light extracting pattern, which is exemplary made SiO₂ and is distributed according to an equidistant arrangement of light extracting spots as described above. To evaluate the illumination of each sample, a fixed electric current of 20 mA is applied to each sample of light-emitting diode. FIG. 4 illustrates an example of testing system implementation, in which each sample D is placed on a measuring platform P and a light sensor S is configured to detect and measure the light intensity of each sample as it receives the application of the fixed electric current.

The chart of FIG. 3 gathers the results of the test experiment, where the luminous intensity and other representative electrical parameters of the light-emitting diodes have been measured. The first column “Wafer NO.” indicates the sample number, and the second column indicates the thickness in angstroms (Å) of the light extracting pattern in each sample. Among the electrical characteristics tested in the chart, “V_{fin}” expressed in volts (V) refers to an initial conducting voltage of the light-emitting diode. “V_{f}” is the forward voltage for illuminating the light-emitting diode. “Vᵣ” is the reverse voltage at the breakdown of the light-emitting diode. “Iᵣ” is the leakage current expressed in micro-amperes (μA). “Iᵥ” is the luminous intensity of the light-emitting diode expressed in millicandela (mcd). “λ_{d}” is the dominate wavelength and “λₚ” is the peak wavelength, both characteristics being expressed in nanometers (nm) and indicative of the color emission of the light-emitting diode. In this experiment, the samples are exemplary light-emitting diodes emitting in the blue color range.

In the chart of FIG. 3, a maximum luminous intensity of about 150.2 mcd corresponding to a dominate wavelength λ_{d} of about 458 nm is observed for a thickness of the light extracting pattern of about 500 Å (sample 3). In comparison, a reference sample without light extracting pattern emits a luminous intensity of about 126 mcd (sample 1). For a thickness of the light extracting pattern of about 800 Å (sample 4), the luminous intensity is about 135.5 mcd. As the thickness of the light extracting pattern increases to respectively 1100 Å (sample 5), 1500 Å (sample 6), and 2500 Å (sample 7), it is observed that the luminous intensity of the light-emitting diode does not vary significantly from the light intensity corresponding to the thickness of 800 Å, in particular if the testing and/or measuring errors are considered. For a thickness of the light extracting pattern equal to 3500 Å (sample 8), the light intensity of the light-emitting diode value drops to 124.9 mcd.

The chart of FIG. 3 also shows minor variations of the electrical characteristics V_{fin}, V_{f}, Vᵣ and Iᵣ, which indicates that the electrical characteristics of the light-emitting diode are not affected by the thickness variation of the light extracting pattern.

The test conducted according to this invention thus reveals that the layer thickness of the light extracting pattern is a factor which modifies the light intensity of the light-emitting diode. According to the results of FIG. 3, an improved light-emitting diode should implement a specific thickness range of the light extracting pattern, which is less than 800 Å and preferably around 500 Å. According to an embodiment, a possible thickness range around 500 Å can be set between about 400 Å and 600 Å at production, which can be broadened if necessary to comply with manufacture or design demands.

By forming an array of light extracting spots according to this invention, light extraction is enhanced and the light-emitting diode can have an improved light intensity. A person skilled in the art will readily appreciate that the improved characteristics provided by the light extracting pattern according this invention may be generally implemented for any types of light-emitting diode. In particular, the light extracting pattern according to this invention may be implemented with light-emitting diodes having different layer structures. Additionally, the layer of the light extracting spots can be arranged at different layer levels in the multi-layer structure of the light-emitting diode to accord with different directions of light emission.

Realizations in accordance with the present invention therefore have been described in the context of particular embodiments. These embodiments are meant to be illustrative and not limiting. Many variations, modifications, additions, and improvements are possible. Accordingly, plural instances may be provided for components described herein as a single instance. Structures and functionality presented as discrete components in the exemplary configurations may be implemented as a combined structure or component. These and other variations, modifications, additions, and improvements may fall within the scope of the invention as defined in the claims that follow.

What is claimed is:

1. A light-emitting diode, comprising:
a multi-layer structure including a plurality of nitride semiconductor layers stacked over a surface of a substrate, wherein the multi-layer structure includes a light-emitting layer;
a plurality of electrodes for applying a driving current through the multi-layer structure; and
an optical layer integrated to the multi-layer structure, wherein the optical layer forms an array of substantially equidistant light extracting spots.

2. The light-emitting diode according to claim 1, wherein the light extracting spots have a layer thickness less than about 800 Å.

3. The light-emitting diode according to claim 1, wherein the optical layer is made of a material compound including SiOₓ, SiₓN_{y}, SiC, SiOₓN_{y}, ZnSe, TiO₂, or Ta₂O₅, where x and y are chemical element ratio numbers.

4. The light-emitting diode according to claim 1, wherein the array of light extracting spots is arranged at an interface between two material layers of the multi-layer structure.

5. The light-emitting diode according to claim 1, wherein the array of the light extracting spots includes a distribution of the light extracting spots in juxtaposed hexagon patterns.

6. The light-emitting diode according to claim 5, wherein the light extracting spots are placed at the corners and centre of each hexagon pattern.

7. The light-emitting diode according to claim 1, wherein one light extracting spot has a hexagonal shape.

8. The light-emitting diode according to claim 1, wherein a luminous intensity of the light-emitting diode is above about 150 mcd.

9. A process of forming a light-emitting diode, comprising:
forming a multi-layer structure including at least one light-emitting layer;
forming electrodes for supplying a driving current through the multi-layer structure; and
forming an optical layer integrated to the multi-layer structure, wherein the optical layer includes an array of substantially equidistant light extracting spots.

10. The process according to claim 9, wherein the light extracting spots have a layer thickness less than about 800 Å.

11. The process according to claim 9, wherein forming an optical layer integrated to the multi-layer structure includes forming the optical layer at an interface between two layers of the multi-layer structure.

12. The process according to claim 11, wherein forming an optical layer integrated to the multi-layer structure comprises:
forming an optical layer over a surface of a substrate;
patterning the optical layer to form an array of substantially equidistant light extracting spots; and
stacking a plurality of layers including the light-emitting layer over the optical layer.

13. The process according to claim 12, wherein stacking a plurality of layers over the optical layer includes:
forming a buffer layer covering the optical layer; and
forming a plurality of nitride semiconductor layers on the buffer layer.

14. The process according to claim 12, wherein patterning the optical layer to form an array of substantially equidistant light extracting spots includes performing a photolithography to form a photoresist pattern, and etching through the photoresist pattern.

15. The process according to claim 9, wherein the optical layer is made of a material composition including SiOₓ, SiNₓ, Si₃N₄, SiC, SiOₓN_{y}, ZnSe, TiO₂, or Ta₂O₅, where x and y are chemical element ratio numbers.

16. The process according to claim 9, wherein the array of substantially equidistant light extracting spots includes a distribution of the light extracting spots in juxtaposed hexagon patterns.

17. The process according to claim 16, wherein the light extracting spots are placed at the corners and centre of each hexagon pattern.

18. The process according to claim 9, wherein at least one light extracting spot has a hexagonal shape.

19. The process according to claim 9, wherein the light-emitting diode has a luminous intensity above about 150 mcds.
